(19) United States
(12) Patent Application Publication
(10) Pub. No.: US 2008/0224187 A1
(43) Pub. Date: Sep. 18, 2008

(54) Image Sensor Pixel and Method of Fabricating the Same

(75) Inventors: Cheol Soo Park, Jeju-do (KR); Do Young Lee, Kyeungki-do (KR)

Correspondence Address: CANTOR COLBURN, LLP, 20 Church Street, 22nd Floor, Hartford, CT, 06103, US

(73) Assignees: Cheol Soo PARK, Jeju-si (KR); SILICONFILE TECHNOLOGIES INC., Seoul (KR)

(21) Appl. No.: 11/997,843

(22) PCT Filed: Aug. 11, 2006
(86) PCT No.: PCT/KR06/03164

§ 371 Date: Feb. 4, 2008

(30) Foreign Application Priority Data
Aug. 13, 2005 (KR) 10-2005-0074541

(51) Int. Cl. H01L 31/00; H01L 21/00

(52) U.S. Cl. 257/292; 438/57; 257/E31.001; 257/E21.001

(57) ABSTRACT

A new structure of a photodiode of a pixel in CMOS image sensor and a method of fabricating the same are provided. The photodiode is fabricated by using one photo mask, so that the number of masks decreases and the fabrication processes are simplified. In addition, two conducting layers constituting a photodiode are self-aligned, so that a fabrication process for connecting the photodiode and a transfer transistor is not required. Accordingly, a problem of channeling generated in a lower portion of a gate of the transfer transistor can be solved, so that an improved pixel can be fabricated.

### TECHNICAL FIELD

The present invention relates to a complementary metal oxide semiconductor (CMOS) image sensor, and more particularly, to a self-aligned buried channel structure of a transfer transistor in a pixel and a method of fabricating the same.

### BACKGROUND ART

An image sensor is a device for capturing an image by using a characteristic of a semiconductor device having a sensitivity to an external energy such as a photon. Light emitted from an object in nature has a specific energy and a wavelength. A pixel of the image sensor senses the light emitted from the object and converts the light into electrical value. An example of the pixel of the image sensor is a 4-transistor CMOS active pixel.

FIG. 1 is a circuit diagram showing an image sensor constructed with a photodiode 190 and four transistors 110, 120, 130, and 140. Operations of the image sensor circuit are as follows. The photodiode 190 is reset by RX and TX signals in a reset section, and light focused on the photodiode 190 is converted into an electrical signal to be transmitted to an output node Vout through a transfer transistor 110, a driver transistor 130, and a select transistor 140.

A conventional method of fabricating the CMOS image sensor is described with reference to a plan view of FIG. 2.

A node between the transfer transistor 210 and the reset transistor 220 is connected to a gate of the driver transistor 230 by a metallic layer 225 through a contact area.

In the fabrication processes, in order not to form a P-well in an area where the photodiode to be formed, a P-well layer 250 is formed on the area.

An N-type photodiode region (PDN) layer 260 which is a cathode of the photodiode 190 shown in FIG. 1 is formed by performing an N-type impurity ion implantation process. A P-type photodiode region (PDP) layer 280 which is an anode of the photodiode 190 is formed by performing a P-type impurity ion implantation process. An area where the PDN and PDP layers 260 and 280 are overlapped with each other becomes PN-junction area, that is, an effective area of the photodiode 190.

Now, processes for fabricating the image sensor having the conventional pinned photodiode will be described with reference to FIGS. 3 to 6.

FIGS. 3 to 6 are sectional views showing only the photodiode 190 and the transfer transistor 210 in a pixel 100 in order to explain the fabrication processes.

A fabrication process shown in FIG. 3 is similar to the fabrication process for a general CMOS transistor. A gate portion of the transfer transistor 210 is formed with polysilicon, and a source region 315 of the transfer transistor 210 is formed by performing an ion implantation process. Here, unlike the fabrication method of the general CMOS transistor, only N-type ions are implanted to form the source region 315. In this case, an N ion implantation layer mask 285 shown in FIG. 2 is used to form only the source region 315. Here, a photoresist 313 is formed by a photo masking process using the N ion implantation layer 285 as a mask shown in FIG. 2.

Next process for forming the cathode 160 of the photodiode 190 is described with reference to FIG. 4. A photo mask 310 is formed using the N-type mask layer 260 of the photodiode 190, and negative electrode 330 of the photodiode 190 is formed by performing the N-type ion implantation process.

Next, as shown in FIG. 5, in order to form an area for connecting the transfer transistor 210 and the photodiode 190, the N-type ion implantation process is performed again using the same N-type mask layer 260. Here, a thickness of a layer where ions are implanted is smaller than the thickness of the negative electrode area 330 of the photodiode 190, but the implanted ions entirely penetrates the gate 210 of the transfer transistor to form an N-type connecting area 340 in a silicon substrate. When the transfer transistor 210 is turned on, the negative electrode area 330 of the photodiode 190 and the transfer transistor 210 are connected with each other.

Next, the source region 351 is formed by using a source/drain ion implantation mask layer (not shown), the fabrication process therefore is similar to the fabrication process for the general CMOS. Here, a spacer 353 is formed in advance on a side wall of the gate of the transfer transistor 210 to form the source region 351 of the transfer transistor 210 in lightly doped drain (LDD) structure. The spacer process is widely known in CMOS fabrication processes, so that detailed description thereof is omitted.

Next, in order to form a positive electrode area 350 (PDP) of the photodiode 190, the photo masking process is performed to remain the photoresist 355, and the positive electrode 350 of the photodiode 190 is formed by the P-type ion implantation process. Therefore, the positive electrode area 350 is entirely surrounded by the negative electrode area 330 due to the spacer 353.

However, the processes for fabricating the conventional pinned photodiode have problems. The problems are described with reference to FIG. 7 showing in detail the fabrication process for forming the negative electrode of the photodiode.

The ion implantation process is performed to form the N-type connecting area 340. The energy of the implanted ions is so high that the ions can penetrate the gate of the transfer transistor 210 of a semiconductor surface. Here, the photoresist 310 has a function of an ion implantation stopper, so that ions are not implanted in a predetermined portion of the gate 210. The portion where the ions are not implanted becomes practically effective channel length Leff of the transistor. However, in a photolithography process for forming the photoresist 310 in the semiconductor fabrication processes, the photoresist 310 may be mis-aligned.

For example, in FIG. 7, an accurate position of the photoresist 310 is denoted by a1. When the photoresist 310 is mis-aligned to the left, the photoresist 310 is positioned at a2. When the photoresist 310 is mis-aligned to the right, the photoresist 310 is positioned by a3. Due to mis-alignment, the effective channel length Leff of the transfer transistor deviates from a desired value to other values.

The transfer transistor needs to transmit electrical signals from the photodiode without loss thereof. However, due to deviation in the effective channel length, signal transmitting property may be changed.

In addition, due to deviation in the effective channel length, an undesired charge in currents of the transfer transistor may cause noises.

In addition, the N-type connecting area 340 on which ions are concentrated exists in only a portion under the gate of the transfer transistor 210, so that image lagging caused from a delay in transmission of electric charges occurs, and a dark signal source may be generated.

To solve the aforementioned problems, in the conventional method, the channel length of the gate of the transfer transistor is formed to be unnecessarily long to maintain a predetermined channel length.

Therefore, a fabrication process capable of regularly maintaining the effective channel length of the transfer transistor in the image sensor as well as connecting the photodiode and the transfer transistor is required.

### DISCLOSURE OF INVENTION

### Technical Problem

An object of the present invention is to maintain an effective channel length of a gate of a transfer transistor forming a pixel of an image sensor.

Another object of the present invention is to provide a method of fabricating a transfer transistor of a pixel without image lagging.

Another object of the present invention is to provide an economical image sensor fabricated by a simple process.

### Technical Solution

According to an aspect of the present invention, there is provided a pixel of an image sensor including: a semiconductor substrate; a trench area formed on a portion in the semiconductor substrate; and a photodiode formed through the trench area.

According to another aspect of the present invention, there is provided a pixel of an image sensor including: a semiconductor substrate; a trench area formed on a portion in the semiconductor substrate; and a photodiode having an electrode including at least a portion of a side wall of the trench area.

According to another aspect of the present invention, there is provided a pixel of an image sensor including: a semiconductor substrate; a trench area formed on a portion in the semiconductor substrate; and a photodiode having an electrode including at least a portion of a side wall or a lower portion of the trench area.

According to another aspect of the present invention, there is provided a pixel of an image sensor including: a semiconductor substrate; a trench area formed on a portion in the semiconductor substrate; and a photodiode having the one electrode formed through the trench area and the other electrode formed through the trench area.

According to an aspect of the present invention, there is provided a method of fabricating a pixel of an image sensor including steps of: (a) forming a trench area on a semiconductor substrate; and (b) implanting ions to form an electrode of a photodiode through the trench area.

According to another aspect of the present invention, there is provided a method of fabricating a pixel of an image sensor including: (a) a step of forming a trench area on a semiconductor substrate; (b) a first ion implantation step of implanting ions to form the one electrode of a photodiode through the trench area; and (c) a second ion implantation step of implanting ions to form the other electrode of the photodiode through the trench area.

According to another aspect of the present invention, there is provided a method of fabricating a pixel of an image sensor including: (a) a step of forming a trench area on a semiconductor substrate; (b) a first ion implantation step of performing tilted ion implantation process to form the one conducting layer of a photodiode through the trench area; and (c) a second ion implantation step of implanting ions to form the other conducting layer of the photodiode through the trench area.

According to another aspect of the present invention, there is provided a method of fabricating a pixel of an image sensor including: (a) a step of forming a trench area on a semiconductor substrate; (b) a first ion implantation step of performing tilted ion implantation process to form the one conducting layer of a photodiode through the trench area; (c) a second ion implantation step of implanting ions to form the one conducting layer of the photodiode through the trench area; and (d) a third ion implantation step of implanting ions to form the other conducting layer of the photodiode through the trench area.

### BRIEF DESCRIPTION OF THE DRAWINGS

The above and other features and advantages of the present invention will become more apparent by describing in detail exemplary embodiments thereof with reference to the attached drawings in which:

FIG. 1 is a circuit diagram showing a CMOS image sensor having a 4-transistor structure;

FIG. 2 is a plan view showing a structure of a pixel of an image sensor having a conventional pinned photodiode;

FIG. 3 is a view showing a first process for fabricating the image sensor of FIG. 2;

FIG. 4 is a view showing a second process for fabricating the image sensor of FIG. 2;

FIG. 5 is a view showing a third process for fabricating the image sensor of FIG. 2;

FIG. 6 is a view showing a fourth process for fabricating the image sensor of FIG. 2;

FIG. 7 is a sectional view showing a pixel for explaining a problem of a conventional art;

FIG. 8 is a view showing a first process for fabricating an image sensor according to an embodiment of the present invention;

FIG. 9 is a view showing a second process for fabricating an image sensor according to an embodiment of the present invention;

FIG. 10 is a view showing a third process for fabricating an image sensor according to an embodiment of the present invention;

FIG. 11 is a view showing a fourth process for fabricating an image sensor according to an embodiment of the present invention;

FIG. 12 is a view showing a fifth process for fabricating an image sensor according to an embodiment of the present invention;

FIG. 13 is a view showing a sixth process for fabricating an image sensor according to an embodiment of the present invention;

FIG. 14 is a view showing a seventh process for fabricating an image sensor according to an embodiment of the present invention;

FIG. 15 is a view showing a eighth process for fabricating an image sensor according to an embodiment of the present invention;

FIG. 16 is a view showing a ninth process for fabricating an image sensor according to an embodiment of the present invention; and

FIG. 17 is a view showing a tenth process for fabricating an image sensor according to an embodiment of the present invention.

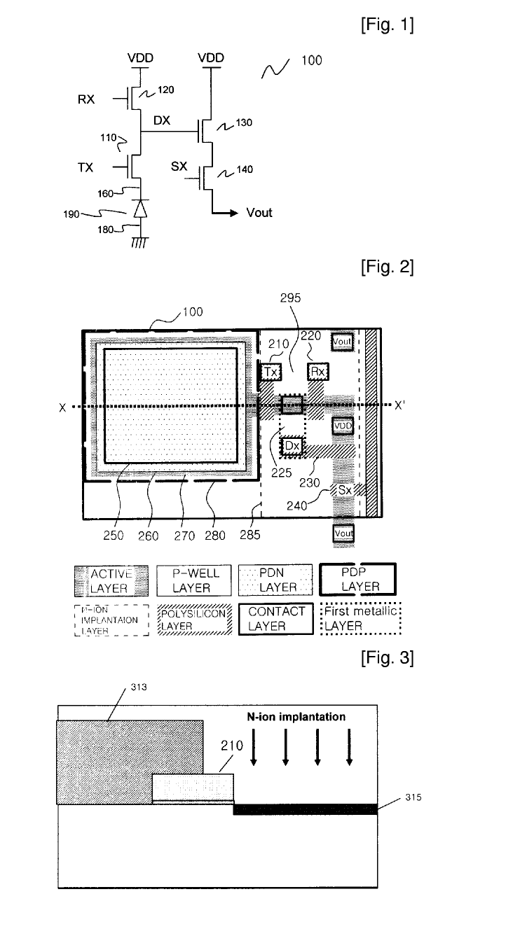

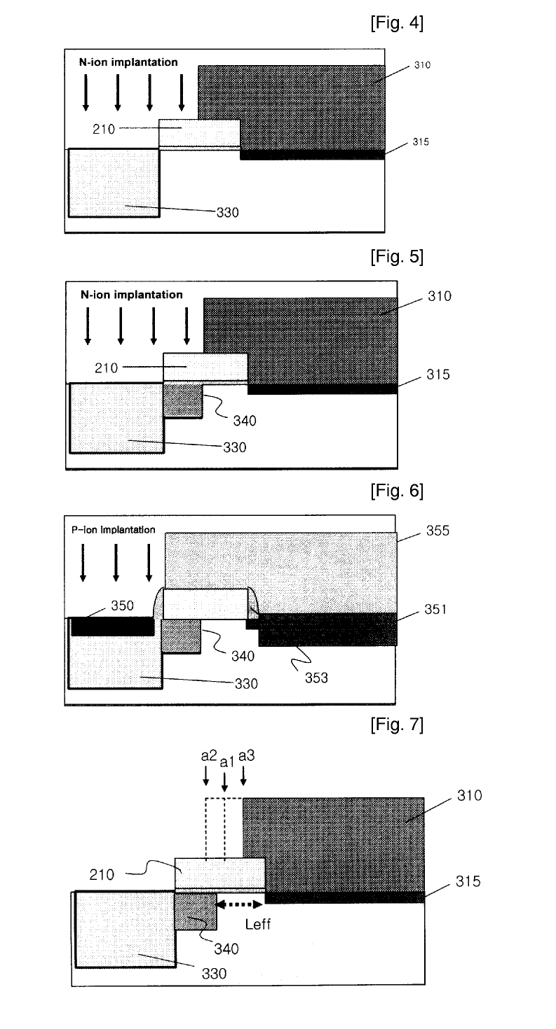

### BEST MODE FOR CARRYING OUT THE INVENTION

The attached drawings for illustrating exemplary embodiments of the present invention are referred to in order to gain a sufficient understanding of the present invention, the merits thereof, and the objectives accomplished by the implementation of the present invention.

Hereinafter, the present invention will be described in detail by explaining exemplary embodiments of the invention with reference to the attached drawings. Like reference numerals in the drawings denote like elements.

It should be noted that, in the following description, all processes for fabricating a semiconductor are not described, but only the main processes are described. Although only the main processes are described, it will be understood by those skilled in the art.

A P-type silicon substrate 500 provided in advance is formed with a pad oxide 501 thereon and coated with a nitride layer 502. After that, a field mask is formed on a portion of the semiconductor substrate 500, and the semiconductor substrate 500, the pad oxide 501, and the nitride layer 502 are etched to form trench areas 510.

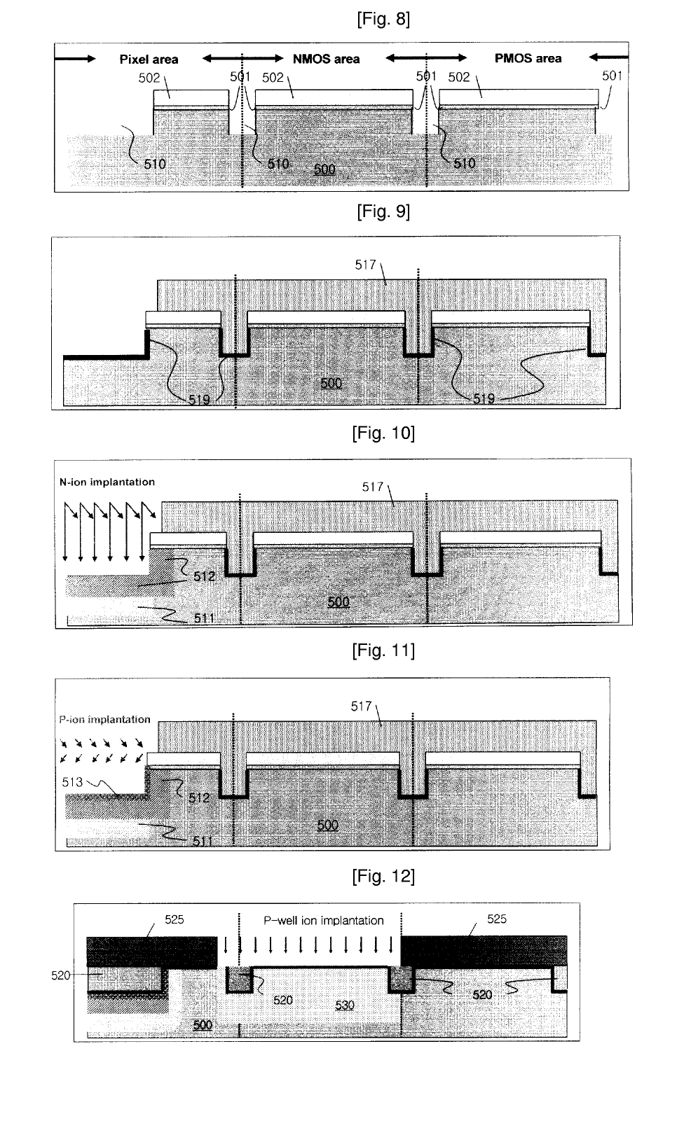

The semiconductor substrate 500 may be an epitaxial wafer having a property of about 10˜15 ohm-cm for a low leakage characteristic of a semiconductor image sensor (see FIG. 8).

In the trench areas 510 formed by etching using a mask 517 for forming a photodiode, a thin oxide layer 519 is suitably formed as a linear oxidation (see FIG. 9)

Two ions implantation processes are performed to form a negative electrode of the photodiode. The first ion implantation process is performed without tilting, so that a deep N-type area 511 of the photodiode is formed in the trench area 510 toward the bottom of the trench area 510. Here, phosphorus is used for the implanted ion, and implantation energy may be 300 KeV or more. For the convenience of description, a magnitude of the implantation energy is represented as vertical arrows in FIG. 10.

The second ion implantation process is performed with tilting to a vertical line of a surface of the semiconductor substrate 500. Here, in order to sufficiently implant the ions in a side wall between the trench area 510 and the transfer transistor, the ions need to be implanted in a specific tilt direction. Here, a tilting angle may be arbitrarily adjusted, but preferably in a range of from about 15° to about 60° Phosphorus is used for the implanted ion, and implantation energy may be 100 Kev. For the convenience of description, a magnitude of the implantation energy is represented as tilted arrows in FIG. 10.

By the second tilted ion implantation process, the N-type area 512 is suitably formed on the side wall of the trench area 510 as well as the bottom thereof, and N-type area 512 and the deep N-type area 511 constitute the double-type negative electrode of the photodiode.

Unlike the aforementioned conventional art, the two ion implantation processes are performed before the gate is formed. In the conventional method, the ion implantation process for forming the negative electrode of the photodiode is performed after the gate is formed, so that problems of mis-aligning and channeling occur. However, according to the present invention, the aforementioned problems can be minimized.

P-type ions are implanted to form a positive electrode of the photodiode. During implantation, the tilted ion implantation process is performed in four directions such that the positive electrode sufficiently covers the negative electrodes 511 and 512. In FIG. 11, tilted arrows are represented to show tilted P-type ion implantation process in four directions.

Next, an oxide layer 520 is coated on the trench area 510 to fill therein, and chemical mechanical polishing (CMP) process is performed to flat the oxide layer 520. After that, a photo mask 525 is formed by using a P-well mask, and a P-well 530 is formed on the semiconductor substrate 500 by the ion implantation process (see FIG. 12).

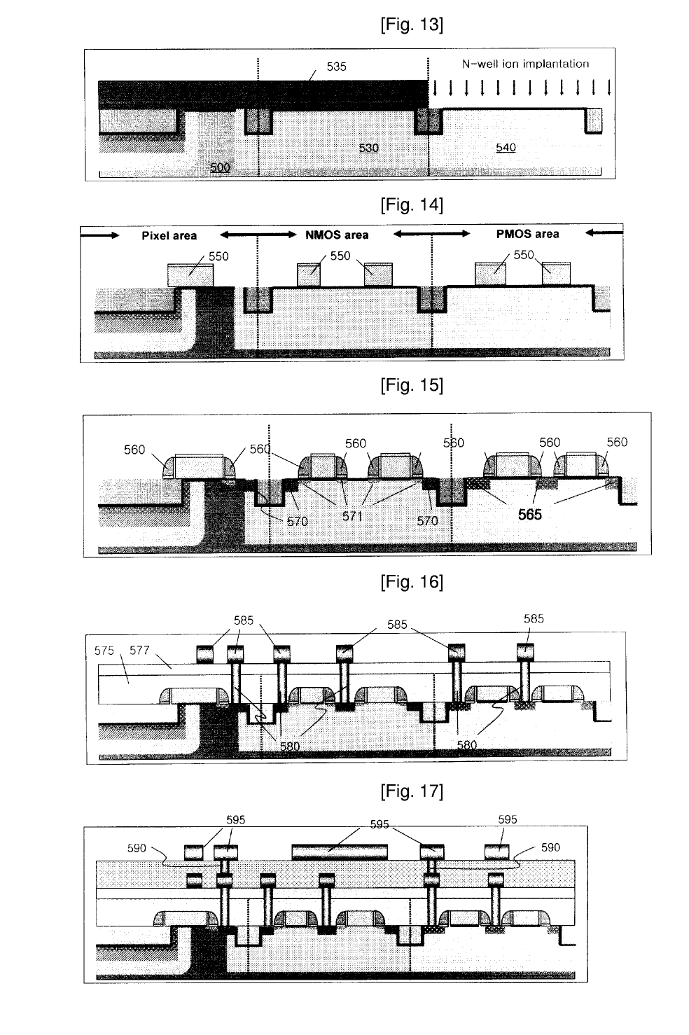

A photo mask 535 is formed by using an N-well mask to form an N-well 540 on the substrate 500, and the N-well 540 is formed on the semiconductor substrate 500 by the N-type ion implantation process (see FIG. 13).

A polysilicon layer is coated on the substrate 500, and a photo masking process is performed by using a gate mask to remain the gate portions 550. Here, a gate portion remained on a pixel area becomes the gate of the transfer transistor, a gate portion remained on an NMOS area becomes a gate of an N-channel transistor, a gate portion remained on a PMOS area becomes a gate of a P-channel transistor (see FIG. 14).

After spacer oxide layers 560 are formed on the side wall of the gates 550, source/drains 565 of the P-channel transistor are formed by performing the P-type ion implantation process, and source/drains 570 of the N-channel transistor are formed by performing the N-type ion implantation process. Here, the source/drains 570 of the N-channel transistor may be formed in a lightly doped drain (LDD) structure though two processes (see FIG. 15).

A boro-phosphorous silicate glass (BPSG) layer 575 is deposited as an insulating layer, a tetra-ethyl ortho-silicate (TEOS) layer 577 is coated thereon, contact portions 580 are formed by using a mask for forming metal interconnections, and metal interconnections 585 of a first layer are formed (see FIG. 16).

When the metal interconnections are formed on a second layer, second metal contact portions 590 are formed, and second metal interconnections 595 are formed (see FIG. 17).

The semiconductor fabrication processes described above with reference to FIGS. 12 to 17 are similar to a general CMOS fabrication process.

As described above with reference to FIGS. 10 and 11, the processes for fabricating the photodiode of the pixel is simpler than the conventional fabrication processes, so that a low-cost pixel having high electrical characteristic can be fabricated.

While the present invention has been particularly shown and described with reference to exemplary embodiments thereof, it will be understood by those skilled in the art that various changes in form and details may be made therein without departing from the spirit and scope of the present invention as defined by the appended claims.

### INDUSTRIAL APPLICABILITY

According to the present invention, when a photodiode of a pixel is formed, negative and positive electrodes of the photodiode can be formed by using only one photo masking layer.

According to another aspect of the present invention, two ion implantation processes for forming the negative electrode of the photodiode are performed. The one ion implantation process is performed with tilting, so that a process for connecting the photodiode and a transfer transistor is not required.

According to another aspect of the present invention, the negative and positive electrodes of the photodiode are formed before a gate of a pixel transistor is formed, so that the negative and positive electrodes of the photodiode are self-aligned. In addition, a problem of deviation in an effective channel length due to mis-alignment and gate channeling problem are solved at the same time, so that the pixel having high electrical characteristic can be fabricated.

According to another aspect of the present invention, a mask layer used to form a portion connecting the photodiode and the transfer transistor by tilted ion implantation process and a method of fabricating the same are not required.

According to the present invention, masks used for fabrication processes for the pixel decrease, so that costs of the mask and production costs of the image sensor reduce.

1-32. (canceled)

33. A pixel of an image sensor comprising:
a semiconductor substrate;
a trench area formed on a portion in the semiconductor substrate; and
a photodiode formed through the trench area,
wherein the photodiode is formed by performing two or more ion implantation processes.

34. The pixel according to claim 33, wherein the photodiode comprises the one electrode formed by performing two or more ion implantation processes and the other electrode formed by performing another ion implantation process.

35. The pixel according to claim 33, wherein the trench area is formed by etching.

36. The pixel according to claim 33, wherein the photodiode comprises an electrode formed by performing one or more tilted ion implantation processes.

37. The pixel according to claim 36, wherein at least one electrode of the photodiode is positioned at a side wall of the trench area.

38. The pixel according to claim 37, wherein the one electrode is negative electrode.

39. The pixel according to claim 33,
wherein the photodiode have an electrode including at least a portion of a side wall portion or a lower portion of the trench area, and
wherein the electrode is formed by performing two or more ion implantation processes.

40. The pixel according to claim 39, wherein the electrode in at least a portion of the side wall is formed by performing tilted ion implantation process.

41. A pixel of an image sensor comprising:
a semiconductor substrate;
a trench area formed on a portion in the semiconductor substrate; and
a photodiode having the one electrode formed through the trench area and the other electrode formed through the trench area,
wherein the one electrode is formed by two or more tilted ion implantation processes.

42. The pixel according to claim 41, wherein the one electrode is formed by performing tilted ion implantation process.

43. The pixel according to claim 41 wherein the one electrode includes a portion of a side wall of the trench area.

44. A method of fabricating a pixel of an image sensor comprising:
(a) a step of forming a trench area on a semiconductor substrate;
(b) a first ion implantation step of implanting ions to form the one electrode of a photodiode through the trench area; and
(c) a second ion implantation step of implanting ions to form the other electrode of the photodiode through the trench area.

45. The method according to claim 44, wherein the one electrode of the photodiode is a negative electrode.

46. The method according to claim 44, wherein the first ion implantation step comprises one or more ion implantation processes including a tilted ion implantation process.

47. The method according to claim 46, wherein the one or more ion implantation processes are performed by using the same mask layer.

48. A method of fabricating a pixel of an image sensor comprising:
(a) a step of forming a trench area on a semiconductor substrate;
(b) a first ion implantation step of performing tilted ion implantation process to form the one conducting layer of a photodiode through the trench area; and
(c) a second ion implantation step of implanting ions to form the other conducting layer of the photodiode through the trench area.

49. The method according to claim 48, wherein the conducting layer is formed on a side wall of the trench area.

50. A method of fabricating a pixel of an image sensor comprising:
(a) a step of forming a trench area on a semiconductor substrate;
(b) a first ion implantation step of performing tilted ion implantation process to form the one conducting layer of a photodiode through the trench area;
(c) a second ion implantation step of implanting ions to form the one conducting layer of the photodiode through the trench area; and
(d) a third ion implantation step of implanting ions to form the other conducting layer of the photodiode through the trench area,
wherein the third ion implantation step is performed before a gate of a pixel is formed.

51. The method according to claim 50, wherein the first ion implantation step is performed to form the one conducting layer on a side wall of the trench area in the semiconductor substrate.

52. The method according to claim 50, wherein the second ion implantation step is performed to form the one conducting layer on a portion under the trench area in the semiconductor substrate.

53. The method according to claim 50, wherein the first, second, and third ion implantation steps are performed by using a single photo mask layer.

54. The method according to claim 48, wherein, in the (b), the tilted ion implantation process is performed in a specific tilt direction.

55. The method according to claim 48, wherein the one conducting layer has negative type.

56. The method according to claim 48, wherein the one conducting layer is large enough to include the other conducting layer.

57. The method according to claim 50, wherein, in the (b), the tilted ion implantation process is performed in a specific tilt direction.

58. The method according to claim 50, wherein the one conducting layer has negative type.

59. The method according to claim 50, wherein the one conducting layer is large enough to include the other conducting layer.
